(19) United States
(12) Patent Application Publication
(10) Pub. No.: US 2010/0283518 A1
(43) Pub. Date: Nov. 11, 2010

(54) DELAY APPARATUS OF SEMICONDUCTOR INTEGRATED CIRCUIT AND METHOD OF CONTROLLING THE SAME

(76) Inventors: Seung Joon AHN, Ichon-si (KR); Jong Chern LEE, Ichon-si (KR)

Correspondence Address: LADAS & PARRY LLP, 224 SOUTH MICHIGAN AVENUE, SUITE 1600, CHICAGO, IL, 60604, US

(21) Appl. No.: 12/493,831

(22) Filed: Jun. 29, 2009

(30) Foreign Application Priority Data
May 8, 2009 (KR) 10-2009-0040079

(51) Int. Cl. H03L 7/06; H03L 7/00

(52) U.S. Cl. 327/158; 327/161

(57) ABSTRACT

A delay apparatus of a semiconductor integrated circuit includes a control signal generating unit configured to generate a block control signal and a unit control signal in response to a delay control signal; a plurality of delay blocks, connected in series to each other, and configured to generate a delay clock signal by delaying an input clock signal, wherein each of the delay blocks includes a predetermined number of unit delayers, and the plurality of the delay blocks are configured to be selectively activated in response to the block control signal; and a minute delay unit including a predetermined number of unit delayers and configured to generate an output clock signal by delaying the delay clock signal by adjusting an activation number of the provided unit delayers in response to the unit control signal.

### CROSS-REFERENCES TO RELATED PATENT APPLICATION

The present application claims priority under 35 U.S.C 119(a) to Korean Application No. 10-2009-0040079, filed on May 8, 2009, in the Korean Intellectual Property Office, the disclosure of which is incorporated herein by reference in its entirety as set forth in full.

### BACKGROUND

1. Technical Field

The present invention relates to a semiconductor integrated circuit and, more particularly, to a delay apparatus of a semiconductor integrated circuit and a method of controlling the same.

2. Related Art

A semiconductor integrated circuit is implemented by a logic circuit and includes numerous circuit regions that process digital signals such as data, clock signals, and commands. An input/output timing of each of the digital signals must precisely be controlled so that the semiconductor integrated circuit can performs a normal operation. In order to precisely control the timings of the signals, the semiconductor integrated circuit includes delay apparatuses that grants a variable delay time to an input signal in response to a control signal. In particular, the semiconductor integrated circuit includes apparatuses such as a delay locked loop (DLL) circuit in order to control a timing of a clock signal and the DLL circuit includes a delay apparatus for granting the variable delay time therein.

The DLL circuit is used to provide an internal clock signal having a phase earlier than a reference clock signal at a predetermined time by converting an external clock signal. The DLL circuit has a feedback loop structure and includes a delay line that generates a delay clock signal that delays the reference clock signal transferred from a clock input buffer in response to the control signal therein.

In general, the delay apparatus such as the delay line provided in the DLL circuit is implemented by combination of a plurality of unit delayers that are connected in series to each other. In addition, the delay apparatus determines the number of activated unit delayers as a function of a value of the control signal implemented by a digital signal in order to adjust an entire delay amount. However, the general delay apparatus operates to control whether or not to activate the unit delayer for each one. As a result, a time to adjust the delay amount is lengthened. Further, the general delay apparatus includes a plurality of signal lines so as to transmit a control signal of plural bits, such that an occupancy area increases. Accordingly, it is believed that these characteristics serve as elements that substantially hinder high-speed and high-integration implementation of the semiconductor integrated circuit.

### SUMMARY

Embodiments of the present invention provide a delay apparatus of a semiconductor integrated circuit that supports implementation of high-speed and high-integration of the semiconductor integrated circuit and a method of controlling the same are disclosed herein.

In one embodiment, a delay apparatus of a semiconductor integrated circuit includes a control signal generating unit configured to generate a block control signal and a unit control signal in response to a delay control signal; a plurality of delay blocks, connected in series to each other, and configured to generate a delay clock signal by delaying an input clock signal, wherein each of the delay blocks includes a predetermined number of unit delayers, and the plurality of the delay blocks are configured to be selectively activated in response to the block control signal; and a minute delay unit including a predetermined number of unit delayers and configured to generate an output clock signal by delaying the delay clock signal by adjusting an activation number of the provided unit delayers in response to the unit control signal.

In another embodiment, a delay apparatus of a semiconductor integrated circuit includes at least one delay block that has a plurality of unit delayers, wherein the plurality of the unit delayers are collectively controlled; and a minute delay unit connected in series to the delay block, and the minute delay unit includes a plurality of unit delayers, wherein the plurality of unit delayers are individually controlled.

In still another embodiment, a method of controlling a delay apparatus of a semiconductor integrated circuit that includes a delay blocks connected in series to each other and a minute delay unit, includes: generating a block control signal and a unit control signal by decoding a delay control signal; determining an activation number of the plurality of delay blocks in response to the block control signal and generating a delay clock signal by delaying an input clock signal using the activated delay blocks; and determining an activation number of a plurality of unit delayers provided in the minute delay unit in response to the unit control signal and generating an output clock signal by delaying the delay clock signal using the activated unit delayers.

These and other features, aspects, and embodiments are described below in the section “Detailed Description.”

### BRIEF DESCRIPTION OF THE DRAWINGS

Features, aspects, and embodiments are described in conjunction with the attached drawings, in which:

FIG. 1 is a block diagram of an exemplary delay apparatus of a semiconductor integrated circuit according to one embodiment;

FIG. 2 is a configuration diagram of an exemplary third delay block that can be included with the apparatus of FIG. 1 according to one embodiment; and

FIG. 3 is a configuration diagram of an exemplary minute delay unit that can be included with the apparatus of FIG. 1 according to one embodiment.

### DETAILED DESCRIPTION

Hereinafter, preferred embodiments will be described in detail with reference to the accompanying drawings.

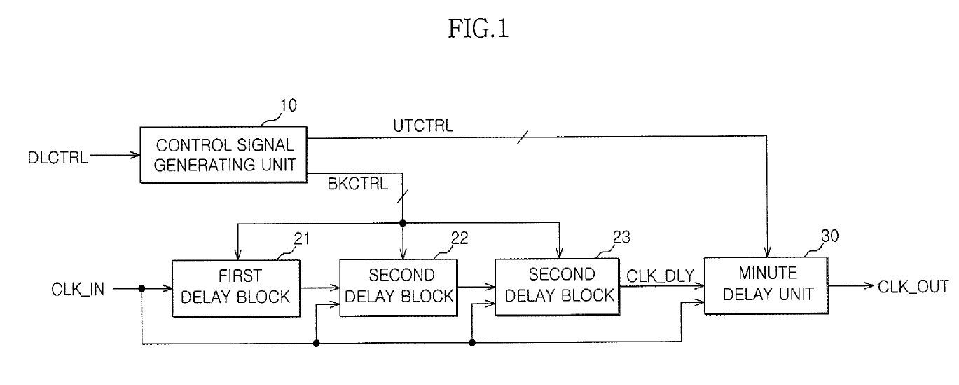

FIG. 1 is a block diagram of an exemplary delay apparatus of a semiconductor integrated circuit according to one embodiment.

As shown in FIG. 1, the delay apparatus of the semiconductor integrated circuit can include a control signal generating unit 10, first to third delay blocks 21 to 23, and a minute delay unit 30.

The control signal generating unit 10 can generate a block control signal ‘BKCTRL’ and a unit control signal ‘UTCTRL’ in response to a delay control signal ‘DLCTRL’. The first to third delay blocks 21 to 23 can generate a delay clock signal ‘CLK_DLY’ by delaying an input clock signal ‘CLK_IN’ in response to the block control signal ‘BKCTRL’. The minute delay unit 30 can generate an output clock signal ‘CLK_OUT’ by delaying the delay clock signal ‘CLK_DLY’ in response to the unit control signal ‘UTCTRL’.

Herein, although total three delay blocks 21 to 23 are provided as one exemplary embodiment, it should be appreciated that two or four or even more delay blocks are included in the scope of the embodiment of the present invention.

The first to third delay blocks 21 to 23 each include the same number of unit delayers. Further, the minute delay unit 30 can also include a plurality of unit delayers. The number of unit delayers that are provided in the minute delay unit 30 should be the same as the number of unit delayers in each of the first to third delay blocks 21 to 23. Herein, each unit delayer is a circuit component that is constituted by a serial combination of two NAND gates.

The delay control signal ‘DLCTRL’ may generally be a signal that is transferred from a delay control device such as a shift register of a DLL circuit. At this time, the delay control signal ‘DLCTRL’ is implemented by a digital code of plural bits and has a predetermined value, such that the delay control signal ‘DLCTRL’ contains information on the number of unit delayers that will be activated among all the unit delayers that are provided in the delay apparatus.

The control signal generating unit 10 should be implemented by a decoder. That is, the control signal generating unit 10 can generate the block control signal ‘BKCTRL’ and the unit control signal ‘UTCTRL’ by decoding the delay control signal ‘DLCTRL’ of plural bits. At this time, each of the block control signal ‘BKCTRL’ and the unit control signal ‘UTCTRL’ is implemented by a combination of a plurality of signals. The control signal generating unit 10 selects an enabled signal among signals included in the block control signal ‘BKCTRL’ and selects an enabled signal among signals included in the delay control signal ‘DCLTRL’ depending on the value of the delay control signal ‘DLCTRL’.

For example, assumed that the value of the delay control signal ‘DLCTRL’ can be 1 to 32 and eight unit delayers are provided in each of the first to third delay blocks 21 to 23 and the minute delay unit 30, the block control signal ‘BKCTRL’ is implemented by a combination of three signals and the unit control signal ‘UTCTRL’ is implemented by a combination of eight signals.

At this time, when the value of the delay control signal ‘DCLTRL’ is equal to or less than 8, the signals included in the block control signals ‘BKCTRL’ are all disabled and that the states of the signals included in the unit control signal ‘UTCTRL’ are determined as a function of the value of the delay control signal ‘DLCTRL’. Further, when the value of the delay control signal ‘DLCTRL’ corresponds to 9 to 16, a signal transferred to the third delay block 23 is enabled among the signals included in the block control signal ‘BKCTRL’ and the states of the signals included in the unit control signal ‘UTCTRL’ are determined to correspond to a value acquired by subtracting 8 from the value of the delay control signal ‘DLCTRL’. Similarly, when the value of the delay control signal ‘DCLTRL’ is 17 to 24, a signal transferred to the second delay block 22 is enabled among the signals included in the block control signal ‘BKCTRL’ and the states of the signals included in the unit control signal ‘UTCTRL’ are determined to correspond to a value acquired by subtracting 16 from the value of the delay control signal ‘DLCTRL’. By the same principle, when the value of the delay control signal ‘DLCTRL’ has 25 to 32, the states of the block control signal ‘BKCTRL’ and the unit control signal ‘UTCTRL’ can also be easily appreciated.

Meanwhile, the first to third delay blocks 21 to 23 are connected in series to each other as shown in the FIG. 1 and are configured to be activated in response to the block control signal ‘BKCTRL’. Herein, in the case of the first to third delay blocks 21 to 23, when the second delay block 22 is activated, then the third delay block is also activated and when the first delay block 21 is activated, then the second delay block 22 is also activated. When the first to third delay blocks 21 to 23 are activated, then the first to third delay blocks 21 to 23 each provide a delay amount by all the unit delayers provided therein to an input clock signal. That is, each of the first to third delay blocks 21 to 23 collectively controls the internal unit delayers. Herein, the clock signal input into each of the first to third delay blocks 21 to 23 may be the input clock signal ‘CLK_IN’ or a clock signal output from the former delay block. Therefore, the activation number of the first to third delay blocks 21 to 23 is determined depending on the state of the block control signal ‘BKCTRL’ corresponding to the value of the delay control signal ‘DLCTRL’. Consequently, an entire delay amount of the first to third delay blocks 21 to 23 are set.

The minute delay unit 30 performs a delay operation with respect to the input clock signal ‘CLK_IN’ or the delay clock signal ‘CLK_DLY’ and adjusts the activation number of unit delayers that are provided therein in response to the unit control signal ‘UTCTRL’. That is, the minute delay unit 30 individually controls the unit delayers that are provided therein. Like this, the minute delay unit 30 serves to adjust the delay amount thereof depending on the state of the unit control signal ‘UTCTRL’ generated by decoding the delay control signal ‘DCLTRL’ and serves to relatively minutely adjust the delay amount thereof in comparison with the first to third delay blocks 21 to 23 of which the delay amount is controlled depending on whether or not the plurality of unit delayers are all activated.

Since the delay apparatus of the semiconductor integrated circuit does not transfer the bit of each control signal to each unit delayer, then it is possible to decrease the number of transmission lines of the control signal. As described above, when the value of the delay control signal ‘DCLTRL’ is 1 to 32, the delay apparatus of the conventional semiconductor integrated circuit includes a total of thirty-two unit delayers, and thus total thirty two signal transmission lines must be provided. However, the delay apparatus of the embodiment of the semiconductor integrated circuit can include only a total of eleven signal transmission lines. Accordingly, an occupancy area of the delay apparatus of the semiconductor integrated circuit according to the embodiment of the present invention decreases, it is possible to support implementation of high integration of semiconductor integrated circuit.

Further, in the case of the delay apparatus of the semiconductor integrated circuit, when an entire delay amount is varied, a delay amount that can be varied at one time can be extended by grouping and controlling the plurality of unit delayers by each group unit. Accordingly, the time needed to set a total delay amount of the delay apparatus of the semiconductor integrated circuit decreases. Therefore the delay apparatus of the semiconductor integrated circuit of the present invention can support high-speed operations of the semiconductor integrated circuit.

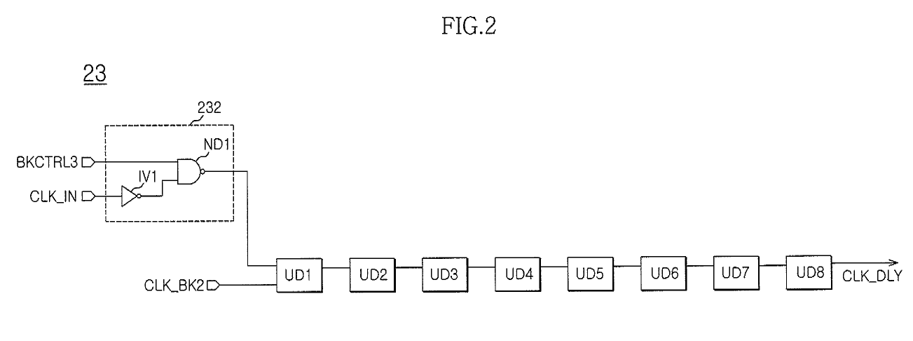

FIG. 2 is a configuration diagram of an exemplary third delay block that can be included with the apparatus of FIG. 1 according to one embodiment. Since the first to third delay blocks 21 to 23 have the same configuration, only the third delay block 23 is illustrated for convenience of description.

As shown in FIG. 2, the third delay block 23 can include an activation unit 232 and eight unit delayers UD<1:8>.

The activation unit 232 determines whether or not the third delay block 23 is activated by passing or interrupting the input clock signal ‘CLK_IN’ in response to a third block control signal ‘BKCTRL3’. Eight unit delayers UD<1:8>, which are arranged in a serial connection form, are configured to output the delay clock signal ‘DLK_DLY’ by delaying a clock signal output from the activation unit 232 or are configured to output the delay clock signal ‘DLK_DLY’ by delaying an output clock signal ‘CLK_BK2’ of the second delay block 22.

Herein, the third block control signal ‘BKCTRL3’ is one of the signals included in the above-mentioned block control signal ‘BKCTRL’.

Although the first to third delay blocks 21 to 23 have the same configuration, the first delay block 21 receives an external supply power VDD instead of an output signal of the former delay block.

The activation unit 232 can include a first inverter IV1 and a first NAND gate ND1. The first inverter IV1 is configured to receive the input clock signal ‘CLK_IN’. The first NAND gate ND1 is configured to receive an output signal of the first inverter IV1 and to receive the third block control signal ‘BKCTRL3’.

In the third delay block 23 configured above, when the third block control signal ‘BKCTRL3’ is disabled, an output signal of the activation unit 232 is at a high level. Each unit delayer is preferably implemented by a combination of NAND gates. Therefore, the most former unit delayer UD1 performs an operation of delaying an output clock signal ‘CLK_BK2’ of the second delay block 22. When the output clock signal ‘CLK_BK2’ of the second delay block 22 is a signal that is activated to be toggled, the output clock signal ‘CLK_BK2’ of the second delay block 22 is output as the delay clock signal ‘CLK_DLY’ by being delayed by eight unit delayers UD<1:8>. On the contrary, when the output clock signal ‘CLK_BK2’ of the second delay block 22 is a signal that is deactivated to have a high-level voltage, the delay clock signal ‘CLK_DLY’ also has a inconsequential high-level voltage.

Meanwhile, when the third block control signal ‘BKCTRL3’ is enabled, the activation unit 232 can drive and output the input clock signal ‘CLK_IN’. In this case, the second delay block 22 is deactivated. As a result, the output clock signal ‘CLK_BK2’ of the second delay block 22 has the inconsequential high-level voltage. Accordingly, the third delay block 23 performs a delay operation with respect to the input clock signal ‘CLK_IN’ to generate the delay clock signal ‘CLK_DLY’.

Herein, eight unit delayers UD<1:8>are provided. Like this, the third delay block 23 performs an operation of delaying the input clock signal ‘CLK_IN’ or the output clock signal ‘CLK_BK2’ of the second delay block 22 by using the delay amount by eight unit delayers UD<1:8>as one unit. The first and second delay blocks 21 and 22 also perform such an operation. Therefore, the delay amount of the input clock signal ‘CLK_IN’ can be increased and decreased by the larger unit.

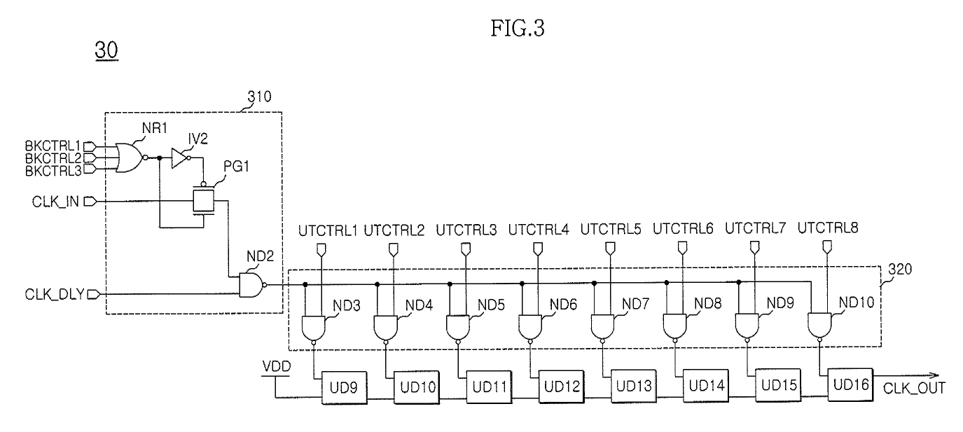

FIG. 3 is a configuration diagram of an exemplary minute delay unit that can be included with the apparatus of FIG. 1 according to one embodiment.

As shown in FIG. 3, the minute delay unit 30 can include a clock signal selecting unit 310, a path setting unit 320, and eight unit delayers UD<9:16>.

The clock signal selecting unit 310 can selectively output the input clock signal ‘CLK_IN’ or the delay clock signal ‘CLK_DLY’ in response to first to third block control signals ‘BKCTRL1’ to ‘BKCTRL3’. The path setting unit 320 can set a delay path of a clock signal output from the clock signal selecting unit 310 in response to first to eighth unit control signals ‘UTCTRL1’ to ‘UTCTRL8’. Eight unit delayers UD<9:16>, which are serially connected, can output the output clock signal ‘CLK_OUT’ by delaying a clock signal transferred from the path setting unit 320.

The first to third block control signals ‘BKCTRL1’ to ‘BKCTRL3’ are the signals included in the above-mentioned block control signal ‘BKCTRL’, respectively. Further, the first to eighth unit control signals ‘UTCTRL1’ to ‘UTCTRL8’ are the signals included in the above-mentioned unit control signal ‘UTCTRL’, respectively.

The clock signal selecting unit 310 can include a first NOR gate NR1, a second inverter IV2, a first pass gate PG1, and a second NAND gate ND2.

The first NOR gate NR1 can receive the first to third block control signals ‘BKCTRL1’ to ‘BKCTRL3’. The second inverter IV2 can receive an output signal of the first NOR gate NR1. The first pass gate PG1 can pass the input clock signal ‘CLK_IN’ in response to an output signal of the first NOR gate NR1 and an output signal of the second inverter IV2. The second NAND gate ND2 is configured to receive an output signal of the first pass gate PG1 and configured to receive the delay clock signal ‘CLK_DLY’.

In the clock signal selecting unit 310 configured above, when any one signal of the first to third block control signals ‘BKCTRL1’ to ‘BKCTRL3’ is enabled, the first NOR gate NR1 can output a low-level signal. Therefore, the first pass gate PG1 is turned off. Accordingly, the clock signal selecting unit 310 can inversely drive and output the delay clock signal ‘CLK_DLY’. In this case, any one of the first to third delay blocks 21 to 23 is activated and as a result, the delay clock signal ‘CLK_DLY’ is normally toggled, such that the minute delay unit 30 performs a delay operation therefor.

On the contrary, when the first to third block control signals ‘BKCTRL1’ to ‘BKCTRL3’ are all disabled, the first NOR gate NR1 can output a high-level signal. Therefore, the first pass gate PG1 is turned on which passes the input clock signal ‘CLK_IN’. In this case, the first to third delay blocks 21 to 23 are all deactivated and as a result, the delay clock signal ‘CLK_DLY’ is transferred as a inconsequential high-level signal, such that the second NAND gate ND2 can inversely drive and output the input clock signal ‘CLK_IN’. That is, the minute delay unit 30 performs the delay operation for the input clock signal ‘CLK_IN’.

The path setting unit 320 can include third to tenth NAND gates ND3 to ND10 that each receive a signal output from the clock signal selecting unit 310 at a first input terminal thereof and respectively receive the first to eighth unit control signals ‘UTCTRL1’ to ‘UTCTRL8’ at a second input terminal thereof.

According to the above configuration, the path setting unit 320 can activate anyone of the NAND gates (i.e., ND3 to ND10) into which one enabled signal among the first to eighth unit control signals ‘UTCTRL1’ to ‘UTCTRL8’ is respectively input and the path setting unit 320 can inversely drive and output the signal output from the clock signal selecting unit 310 through the respectively activated NAND gate.

At this time, the number of activated unit delayers among eight unit delayers UD<9:16>is set depending on which NAND gate among the third to tenth NAND gates ND3 to ND10 is activated. For example, when the eighth unit control signal ‘UTCTRL8’ among the first to eighth unit control signals ‘UTCTRL1’ to ‘UTCTRL8’ is enabled, only one unit delayer UD<16> is activated and the minute delay unit 30 provides a minimum delay value. On the contrary, when the first unit control signal ‘UTCTRL1’ is enabled, all the eight unit delayers UD<9:16> are activated. At this time, the minute delay unit 30 provides a maximum delay value.

As described above, the delay apparatus of the semiconductor integrated circuit can include a plurality of delay blocks that are connected to each other in series, a minute delay unit, and a control signal generating unit. In addition, the delay apparatus generates a block control signal and a unit control signal by decoding a delay control signal using the control signal generating unit. Thereafter, the activation number of the plurality of delay blocks is determined by using the block control signal and a delay clock signal is generated by delaying an input clock signal with the activated delay blocks. The activation number of a plurality of unit delayers that are provided in the minute delay unit is determined in response to the unit control signal and an output clock signal is generated by delaying the delay clock signal with the activated unit delayer.

Since the delay apparatus of the semiconductor integrated circuit that performs such an operation does not transfer bits of a control signal to all unit delayers, the number of transmission lines for the control signal can be reduced. Accordingly, an occupancy area can be reduced and implementation of high-integration of the semiconductor integrated circuit can be supported. Further, a plurality of unit delayers is used as one unit and a delay amount is varied by the unit, such that a delay amount that can be varied at one time can be increased. Accordingly, the time needed to set a total delay amount of the delay apparatus of the semiconductor integrated circuit decreases, thereby supporting implementation of a high-speed semiconductor integrated circuit.

While certain embodiments have been described above, it will be understood that the embodiments described are by way of example only. Accordingly, the device and the method described herein should not be limited based on the described embodiments. Rather, the devices and methods described herein should only be limited in light of the claims that follow when taken in conjunction with the above description and accompanying drawings.

What is claimed is:

1. A delay apparatus of a semiconductor integrated circuit, comprising:
a control signal generating unit configured to generate a block control signal and a unit control signal in response to a delay control signal;
a plurality of delay blocks, connected in series to each other, and configured to generate a delay clock signal by delaying an input clock signal, wherein each of the delay blocks includes a predetermined number of unit delayers, and the plurality of the delay blocks are configured to be selectively activated in response to the block control signal; and
a minute delay unit including a predetermined number of unit delayers and configured to generate an output clock signal by delaying the delay clock signal by adjusting an activation number of the provided unit delayers in response to the unit control signal.

2. The delay apparatus of claim 1, wherein each of the unit delayers provided in the plurality of delay blocks and in the minute delay unit is a circuit component comprising a serial combination of two NAND gates.

3. The delay apparatus of claim 1, wherein the delay control signal is a signal transferred from a shift register of a delay locked loop (DLL) circuit.

4. The delay apparatus of claim 1, wherein the control signal generating unit is implemented by a decoder and each of the block control signal and the unit control signal are implemented by a combination of a plurality of signals, and
wherein the control signal generating unit is configured to select an enabled signal from among signals included in the block control signal and an enabled signal from among signals included in the delay control signal depending on a value of the delay control signal.

5. The delay apparatus of claim 4, wherein when each delay block is activated each of the plurality of delay blocks is configured to grant a corresponding delay to all the unit delayers provided therein to an input clock signal.

6. The delay apparatus of claim 5, wherein each of the plurality of delay blocks includes:
an activation unit configured to determine whether or not a corresponding delay block is activated by passing or interrupting the input clock signal in response to anyone predetermined signal of the signals included in the block control signal; and
a plurality of unit delayers, connected in series to each other, and configured to output the delay clock signal by delaying an clock signal output from the activation unit or by delaying an output clock signal of a former delay block.

7. The delay apparatus of claim 4, wherein the minute delay unit includes:
a clock signal selecting unit configured to selectively output the input clock signal or the delay clock signal in response to the block control signal;
a path setting unit configured to set a delay path of the clock signal output from the clock signal selecting unit in response to the unit control signal; and
a plurality of unit delayers, connected in series to each other, and configured to output the output clock signal by delaying the clock signal set by the path setting unit,
wherein the activation number of the plurality of unit delayers is depends on the delay path of the clock signal set by the path setting unit.

8. A delay apparatus of a semiconductor integrated circuit, comprising:
at least one delay block including a plurality of unit delayers, wherein the plurality of the unit delayers are collectively controlled; and
a minute delay unit that is connected in series to the delay block, and the minute delay unit includes a plurality of unit delayers, wherein the plurality of the unit delayers are individually controlled.

9. The delay apparatus of claim 8, wherein the delay block is configured to be activated or not in response to a block control signal.

10. The delay apparatus of claim 9, wherein the minute unit is configured, in response to a unit control signal, to determine whether or not to activate each unit delayer.

11. The delay apparatus of claim 10, further comprising:
a control signal generating unit configured to generate the block control signal and the unit control signal by decoding a delay control signal transferred from a shift register of a delay locked loop (DLL) circuit.

12. The delay apparatus of claim 8, wherein each of the delay block and the unit delayers provided in the minute delay unit is a circuit component comprising two NAND gates in series.

13. The delay apparatus of claim 9, wherein the delay block includes:
an activation unit configured, in response the block control signal, to determine whether or not the delay block is activated by passing or interrupting an input clock signal; and
a plurality of unit delayers, connected in series to each other, and configured to delay and to output a clock signal output from the activation unit or to output an output clock signal of the former delay block.

14. The delay apparatus of claim 10, wherein the minute delay unit includes:
a clock signal selecting unit configured, in response to the block control signal, to selectively output the input clock signal or the delay clock signal;
a path setting unit configured, in response to the unit control signal, to set a delay path of a clock signal output from the clock selecting unit; and
a plurality of unit delayers, connected in series to each other, and configured to output the output clock signal by delaying the clock signal transferred from the path setting unit,
wherein the activation number of the plurality of unit delayers is dependent on the delay path of the clock signal set by the path setting unit.

15. A method of controlling a delay apparatus of a semiconductor integrated circuit that includes a plurality of delay blocks connected to each other in series and a minute delay unit, comprising:
generating a block control signal and a unit control signal by decoding a delay control signal;
determining an activation number of the plurality of delay blocks in response to the block control signal and generating a delay clock signal by delaying an input clock signal using the activated delay blocks; and
determining an activation number of a plurality of unit delayers provided in the minute delay unit in response to the unit control signal and generating an output clock signal by delaying the delay clock signal using the activated unit delayers.

16. The method of claim 15, wherein each of the plurality of delay blocks includes a plurality of unit delayers and each of the unit delayers provided in each of the plurality of delay blocks and the minute delay unit is a circuit component comprising a serial combination of two NAND gates.

17. The method of claim 15, wherein the delay control signal is a signal transferred from a shift register of a delay locked loop (DLL) circuit.

18. The method of claim 15, wherein each of the block control signal and the unit control signal is implemented by a combination of a plurality of signals, and
wherein the decoding the delay control signal selects an enabled signal from among signals included in the block control signal and selects an enabled signal from among signals included in the delay control signal as a function of a value of the delay control signal.

19. The method of claim 15, wherein the generating the delay clock signal activates all the unit delayers provided in the delay block selected by the block control signal.
